(19) United States
(12) Patent Application Publication
(10) Pub. No.: US 2023/0301019 A1
(43) Pub. Date: Sep. 21, 2023

(54) SYSTEM ON A CHIP BASED COOLING SYSTEM

(71) Applicant: Baidu USA LLC, Sunnyvale, CA (US)

(72) Inventor: Tianyi GAO, San Jose, CA (US)

(21) Appl. No.: 17/698,780

(22) Filed: Mar. 18, 2022

(51) Int. Cl. H05K 7/20; G06F 1/20; H01L 23/473

(52) U.S. Cl. CPC H05K 7/20272; G06F 1/20; H01L 23/473; G06F 2200/201

(57) ABSTRACT

An electronic cooling apparatus is disclosed. The apparatus includes a top layer to receive cooling fluid. The apparatus further includes a fluid management core including a multiplicity of microchannel structures to cool electronic components and a multiplicity of fluid channels through which the cooling fluid is distributed to the microchannel structures. The apparatus further includes a base layer that includes a dedicated cooling area for placement of the fluid management core, and the base layer is to provide the cooling fluid to the fluid channels of the fluid management core. The apparatus further includes a sealing layer disposed between the top layer and the bottom layer to seal the fluid management core. The fluid management core provides non-uniform cooling distributions for different configurations and thermal map of a system on a chip.

### FIELD OF THE INVENTION

Embodiments of the present disclosure relate generally to cooling systems. More particularly, embodiments of the disclosure relate to a system on a chip (SoC) based cooling system.

### BACKGROUND

Electronics cooling is very important for computing hardware and other electronic devices, such as central processing unit (CPU) servers, graphics processing unit (GPU) servers, storage servers, networking equipment, edge and mobile systems, on-vehicle computing boxes, and so on. These systems and devices are critical for businesses, as they are the fundamentals of a company’s daily business operation. The designs of the hardware components and electronics packaging need to improve to continuously support the requirements. Cooling of these electronic components has also become quite challenging to ensure they are functioning properly due to the constant provision of design thermal environments. Moreover, the majority of the electronics enclosures and packages introduce different critical thermal challenges which can require significant research and development efforts on designing and identifying cooling system customizations.

Furthermore, thermal management is becoming significantly critical for high performance processors. In some cases, it also impacts on computing technology development and innovation. Also, the computing hardware and processors have become quite expensive, and therefore, cooling reliability is critical to prevent any potential damages, such as fluid leakage. Hardware reliability is also a key to ensure service level agreement. Therefore, it is critical to provide high quality, high reliability and cost effective cooling products and solutions.

### BRIEF DESCRIPTION OF THE DRAWINGS

Embodiments of the invention are illustrated by way of example and not limitation in the figures of the accompanying drawings in which like references indicate similar elements.

FIG. 1 is sectional side view an example electronic cooling apparatus according to an embodiment.

FIG. 2 is exploded view of different layers of the electronic cooling apparatus according to an embodiment.

FIG. 3 is top view of a base layer of the electronic cooling apparatus according to an embodiment.

FIG. 4 is a side view of another example electronic cooling apparatus according to an embodiment.

FIG. 5 is a top view of a fluid management core being integrated with a dedicated area according to an embodiment.

FIG. 6 is a top view of the fluid management core integrated with a base layer according to an embodiment.

FIG. 7 is a top view of an electronic cooling apparatus having an advanced fluid management core according to an embodiment.

FIG. 8 is a flow diagram illustrating a method of producing an electronic cooling apparatus according to an embodiment.

### DETAILED DESCRIPTION

Various embodiments and aspects of the inventions will be described with reference to details discussed below, and the accompanying drawings will illustrate the various embodiments. The following description and drawings are illustrative of the invention and are not to be construed as limiting the invention. Numerous specific details are described to provide a thorough understanding of various embodiments of the present invention. However, in certain instances, well-known or conventional details are not described in order to provide a concise discussion of embodiments of the present inventions.

Reference in the specification to “one embodiment” or “an embodiment” means that a particular feature, structure, or characteristic described in conjunction with the embodiment can be included in at least one embodiment of the invention. The appearances of the phrase “in one embodiment” in various places in the specification do not necessarily all refer to the same embodiment.

Embodiments of the disclosure provide a solution for designing and building liquid cooling cold plate for advanced chips, such as system on a chip (SoC). The design aims to provide high compatible and flexible design for the chip liquid cooling hardware. Embodiments of the design described herein include, but not limited to, the ease to build different plate for different chips, accommodation of different die sizes, accommodation of different artificial intelligence (AI) devices, efficient heat extracting design and fluid management, non-uniform power mapping on a single chip, SoC or device, efficient thermal management of high power density chips, accommodation of different server hardware and electronics components, efficient fluid microchannel design, accommodation of different cooling systems, high interoperability and the ease to manufacture and assemble.

In some embodiments, the solution presented herein enables the building of different cooling plates including the cooling performance, fluid management, internal microchannel design, non-uniform cooling distribution with a single base design. The design may include a base unit, a fluid management core, a sealing layer and a top unit. The base unit may be designed with a dedicated area for running fluid and the internal inlet and outlet channels. The fluid management core may be designed for regulating fluid flowing and forming different fluid stream patterns through microchannel structures. The core unit may also include the inlet and outlet connections with the base unit. The fluid management core is designed to be implemented to the dedicated area. The sealing layer may be attached on the top of the fluid management core and the top unit is on the top of all the units with the inlet and outlet port connecting to the inlet and outlet channels of the base unit through the channels.

According to a first aspect, an electronic cooling apparatus is provided. The apparatus may include a top layer to receive cooling fluid. The apparatus may further include a fluid management core including a multiplicity of microchannel structures to cool electronic components and a multiplicity of fluid channels through which the cooling fluid is distributed to the microchannel structures. The apparatus may further include a base layer that includes a dedicated cooling area for placement of the fluid management core, and the base layer is to provide the cooling fluid to the fluid channels of the fluid management core. The apparatus may further include a sealing layer disposed between the top layer and the bottom layer to seal the fluid management core.

According to a second aspect, an electronic cooling apparatus is provided. The apparatus may include a top layer to receive cooling fluid. The apparatus may further include a multiplicity of fluid management cores, with each fluid management core including a multiplicity of microchannel structures to cool electronic components and a multiplicity of fluid channels through which the cooling fluid is distributed to the microchannel structures. The apparatus may further include a base layer that includes a multiplicity dedicated cooling areas for placement of the fluid management cores, respectively, and the base layer is to provide the cooling fluid to the fluid channels of the fluid management cores. The apparatus may further include a sealing layer disposed between the top layer and the bottom layer to seal the fluid management cores.

According to a third aspect, a method of providing an electronic cooling apparatus is provided. The method may include providing a top layer including fluid ports, a first portion of an inlet channel, and a first portion of an outlet channel. The method may further include providing a sealing layer including a top sealing portion and a leak detection portion. The method may further include providing a fluid management core including a multiplicity of microchannel structures to cool electronic components and a multiplicity of fluid channels through which cooling fluid is distributed to the microchannel structures. The method may further include providing a base layer including a second portion of the inlet channel, a second portion of the outlet channel, and a dedicated cooling area for placement of the fluid management core.

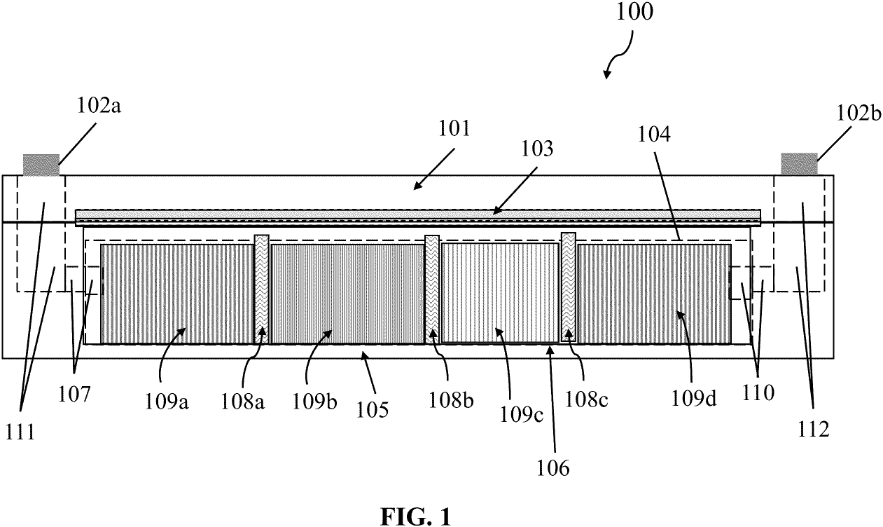

FIG. 1 is sectional view an example electronic cooling apparatus according to an embodiment. Referring to FIG. 1, electronic cooling apparatus 100 (which may be referred to as cold plate) may include a top layer 101, a sealing layer 103, a base layer 105, and a fluid management core (or fluid core) 106. In an embodiment, apparatus 100 may be customizable to fit on any electronic system, such as a chip, SoC, artificial intelligence (AI) device, etc., to cool the electronic system.

As shown, top layer 101 may include fluid ports 102a-b (e.g., connectors attached on a top surface of top layer 101) to connect inlet and outlet fluid channels 111-112 to external sources to provide cooling fluid to and enable warm/hot fluid to escape or exit from electronics cooling apparatus 100. For example, fluid port 102a may connect a cooling fluid source/supply to a first portion of inlet fluid channel 111 to provide cooling fluid from the cooling fluid source/supply through inlet fluid channel 111 and into fluid core 106. Fluid port 102b may connect a heat separator, as an example, to a first portion of outlet fluid channel 112 for warm/hot fluid that exits from fluid core 106 to flow through outlet fluid channel 112 and to the heat separator to separate vapor from the warm/hot fluid and return cooling fluid to the cooling fluid source/supply.

In an embodiment, sealing layer 103 is disposed between the top layer 101 and base layer 105 to seal the fluid core 106. The sealing layer 103 serves to cover substantially or entirely the top region of fluid core 106 to form, with base layer 105, a contained region that completely contains the fluid core 106. In some embodiments, sealing layer 103 may include a top sealing portion and a leak detection portion (or leak detection structure or apparatus). The leak detection structure may be integrated and packaged with sealing layer 103 to detect any fluid that leaks through the seal layer 103.

There are two portions of inlet 107 and outlet 110. This can be understood as inlet 107 and outlet 110 are designed on both the base layer 105 and the fluid management core 106, and they are engaged once the fluid management core 106 is integrated to the base layer 105.

With continued reference to FIG. 1, base layer 105 is configured to hold or support the fluid core 106. Base layer 105 may include a dedicated cooling area or region 104 for integrating fluid core 106 with base layer 105 (e.g., placement of the fluid core 106). Dedicated cooling area (or dedicated area) 104 may be indented to form a cavity for reception of fluid core 106. In an embodiment, base layer 105 may further include a second portion of inlet fluid channel 111 and a second portion of outlet fluid channel 112. Base layer 105 may further include a first portion of inlet 107 and a first portion of outlet 110. As shown in FIG. 1, the first and second portions of fluid channel 111 collectively form fluid channel 111 and the first and second portions of fluid channel 112 collectively form fluid channel 112. The second portion of fluid channel 111 may be connected to the first portion of inlet 107 for cooling fluid to enter fluid core 106 through fluid channel 111 and inlet 107. Correspondingly, the second of fluid channel 112 may be connected to the first portion of outlet 110 for warm/hot fluid to escape from fluid core 106 through outlet 110 and fluid channel 112.

In an embodiment, fluid core 106 may be integrated within dedicated area 104. Fluid core 106 may include a number of microchannel areas or structures 109a-d where cooling fluid is distributed to cool one or more electronic components, such as processor cores, application-specific integrated circuits (ASICs), controller chips, memories, etc. The fluid core 106 may also include a number of fluid channels 108a-c through which the cooling fluid can be delivered to the microchannel areas 109a-d. In the design of apparatus 100, fluid channel 108a is disposed between microchannel areas 109a-b to distribute fluid to the microchannel areas 109a-b. Similarly, fluid channel 108b is disposed between microchannel areas 109b-c, and fluid channel 108c is disposed between microchannel areas 109c-d to distribute fluid to microchannel areas 109b-c and microchannel areas 109c-d, respectively.

The design of microchannel areas 109a-d and fluid channels 108a-c is dependent on the electronic system or the chip, processor, or system on a chip package design. Therefore, the number of microchannel areas 109a-d and fluid channels 108a-c in fluid core 106 is non-limiting and can vary for different electronic systems. As shown in FIG. 1, fluid core 106 may include a second portion of inlet 107 and a second portion of outlet 110 for cooling fluid to enter inlet 107 and flow through fluid channels 108a-c and to microchannel areas 109a-d, and warm/hot fluid to escape from microchannel areas 109a-d and flow through outlet 110.

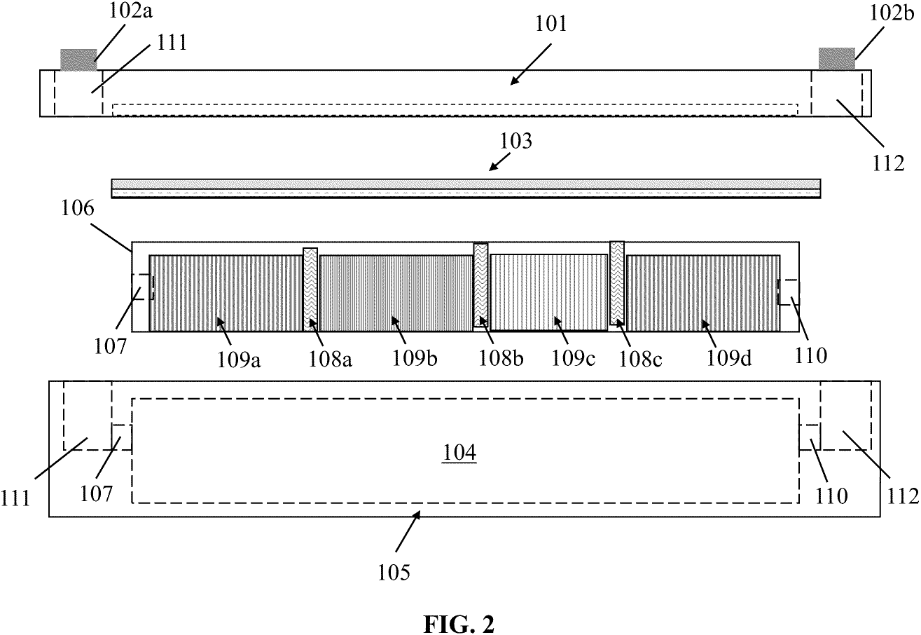

FIG. 2 is sectional view of different layers of the electronic cooling apparatus according to an embodiment. In FIG. 2, top layer 101, sealing layer 103, base layer 105, and fluid core 106 of electronic cooling apparatus 100 are separated to show their corresponding internal structures for device packaging. In this example design, the fluid core 106 is an entirely separated unit and it is designed based on the chip design, such as the configuration and architecture of a SoC. The base layer 105 includes dedicated area 104 designed for the assembling of fluid core 106.

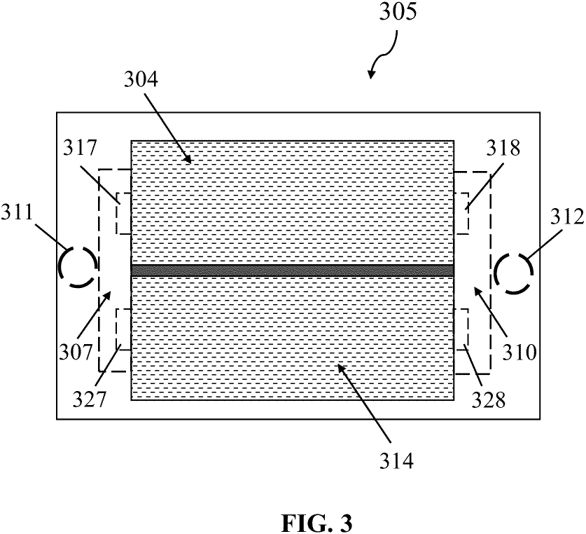

FIG. 3 is top view of a base layer of the electronic cooling apparatus according to an embodiment. In FIG. 3, base layer 305 may include a multiplicity of dedicated cooling areas, such as dedicated areas 304 and 314, for integrating different fluid management cores. In the embodiment of FIG. 3, base layer 305 may include a first opening 311 of one or more inlet fluid channels 307 of base layer 305. In one embodiment, base layer 305 may include an inlet fluid channel 307 connected to a multiplicity of inlet areas or regions, such as inlet areas 317 and 327, to provide cooling fluid to those inlet areas. In another embodiment, base layer 305 may include a multiplicity of inlet fluid channels 307 connected to the inlet areas, with each fluid channel providing cooling fluid, which enters through first opening 311, to its corresponding inlet area.

Still referring to FIG. 3, base layer 305 may further include a second opening 312 of one or more outlet fluid channels 310. In one embodiment, base layer 305 may include an outlet fluid channel 310 that is connected to a multiplicity of outlet areas or regions, such as outlet areas 318 and 328, to enable warm/hot fluid to escape from the different fluid management cores through the outlet areas, the fluid channel 310 and the second opening 312. In another embodiment, base layer 305 may include a multiplicity of fluid channels 310 that are connected to the outlet areas, with each fluid channel receiving outgoing fluid from its corresponding outlet area and directing the fluid towards second opening 312 so that the fluid can escape from the electronic cooling apparatus. Embodiments of the disclosure provide a flexible design that the variation can be implemented on the base layer 305 to better accommodate different fluid management core units. In another embodiment, the base layer 305 can be kept as a standard design and all the variations are to be implemented on the fluid management core.

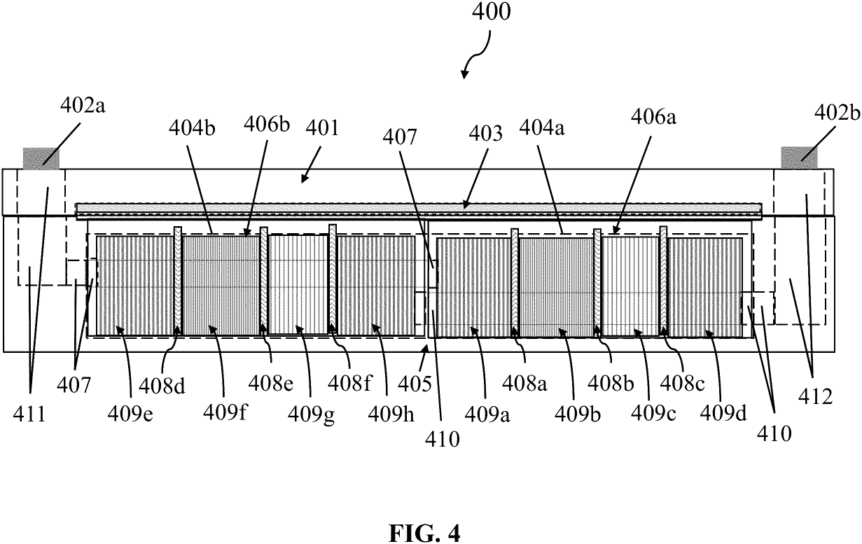

FIG. 4 is a sectional view of another example electronic cooling apparatus according to an embodiment. In FIG. 4, electronic cooling apparatus 400 (which may be referred to as cold plate) may include a top layer 401, a sealing layer 403, a base layer 405, and a multiplicity of fluid management cores (or fluid cores), such as fluid cores 406a-b.

In an embodiment, top layer 401 may include fluid ports 402a-b (e.g., connectors attached on a top surface of top layer 401) to connect inlet and outlet fluid channels 411-412 to external sources to provide cooling fluid to and enable warm/hot fluid to escape or exit from electronics cooling apparatus 400. For example, fluid port 402a may connect a cooling fluid supply to inlet fluid channel 411 to provide cooling fluid from the cooling fluid supply through inlet fluid channel 411 and into fluid cores 406a-b. Fluid port 402b, on the other hand, may connect a heat separator, as an example, to outlet fluid channel 412 for warm/hot fluid that exits from fluid cores 406a-b to flow through outlet fluid channel 412 and out to the heat separator to separate vapor from the warm/hot fluid and return cooling fluid to the cooling fluid supply. In the embodiment of FIG. 4, top layer 401 includes a first portion of fluid channel 411 and a first portion of fluid channel 412.

In an embodiment, sealing layer 403 is disposed between the top layer 401 and base layer 405 to seal the fluid cores 406a-b. The sealing layer 403 is configured to cover substantially or entirely the top region of fluid cores 406a-b to form, in combination with base layer 405, a contained region that completely contains the fluid cores 406a-b. In some embodiments, sealing layer 403 may be integrated and packaged with a leak detection structure or apparatus (not shown) to detect any fluid that leaks through the seal layer 403.

With continued reference to FIG. 4, in an embodiment, base layer 405 is configured to hold or support the fluid cores 406a-b. Base layer 405 may include a multiplicity of dedicated cooling areas or regions, such as dedicated areas 404a-b, for integrating the fluid cores 406a-b with base layer 405 (e.g., placement of fluid cores 406a-b). Each dedicated area may be indented to form a cavity for reception of a fluid core, such as fluid core 406a/406b. In an embodiment, base layer 405 may further include a second portion of fluid channel 411 and a second portion of fluid channel 412. Base layer 405 may further include a first portion of inlet 407 and a first portion of outlet 410. As shown in FIG. 4, the first and second portions of fluid channel 411 collectively form fluid channel 411 and the first and second portions of fluid channel 412 collectively form fluid channel 412. The second portion of fluid channel 411 may be connected to the first portion of inlet 407 for cooling fluid to enter fluid cores 406a-b through fluid channel 411 and inlet 407. Correspondingly, the second of fluid channel 412 may be connected to the first portion of outlet 410 for warm/hot fluid to escape from fluid cores 406a-b through outlet 410 and fluid channel 412.

In an embodiment, fluid cores 406a-b may be integrated within dedicated areas 404a-b, respectively. Fluid core 406a may include a number of microchannel areas or structures 409a-d and fluid core 406b may include a number of microchannel areas or structures 409e-h, where cooling fluid is distributed to cool one or more electronic components, such as processor cores, ASICs, controller chips, memories, etc. The fluid core 406a may also include a number of fluid channels 408a-c through which the cooling fluid can be delivered to the microchannel areas 409a-d. Similarly, the fluid core 406b may also include a number of fluid channels 408d-f through which the cooling fluid can be delivered to the microchannel areas 409e-h.

In the design of apparatus 400, each of the fluid channels 408a-c is disposed between a pair of microchannel areas 409a-d. Similarly, each of the fluid channels 408d-f is disposed between a pair of microchannel areas 409e-h. The design of microchannel areas 409a-h and fluid channels 408a-f in fluid cores 406a-b is dependent on the electronic system. Therefore, the number of microchannel areas 409a-d and 409e-h, and fluid channels 408a-c and 408d-f in fluid cores 406a and 406b, respectively, is non-limiting and can vary for different electronic systems. That is, the number of microchannel areas and fluid channels in fluid core 406a may be different than or the same as those in fluid core 406b.

As shown in FIG. 4, fluid core 406b may include a second portion of inlet 407 that extends from fluid core 406b to fluid core 406a for cooling fluid to enter inlet 407 and flow through fluid channels 408a-f and to microchannel areas 409a-h. Fluid core 406a may include a second portion of outlet 410 that also extends from fluid core 406b to fluid core 406a for warm/hot fluid to escape from microchannel areas 409a-h and flow through outlet 410.

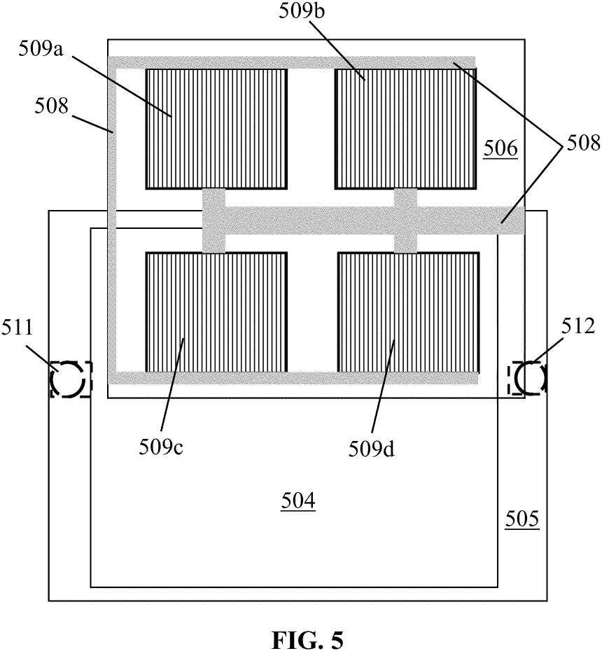

FIG. 5 is a top view of a fluid management core integrated with a dedicated area according to an embodiment. In FIG. 5, base layer 505 may include a dedicated area 504 for placement of fluid management core 506 (e.g., to hold/support fluid management core 506). As shown, base layer 505 may include first opening 511 of an inlet fluid channel (not shown) such that cooling fluid can be provided to the first opening 511, flow through the fluid channel, and enter the fluid management core 506. In an embodiment, base layer 505 may also include a second opening 512 of an outlet fluid channel (also not shown) such that warm/hot fluid can escape from the fluid management core 406 and flow out through the fluid channel and the second opening 512.

Still referring to FIG. 5, fluid management core 506 may include fluid connection channels 508 and microchannel (or fluid heat extension) areas or structures 509a-d. The fluid connection channels 508 are arranged such that incoming cooling fluid entering through the first opening 511 would enter each microchannel area from one side (e.g., an outer side) and outgoing warm/hot fluid would escape from each microchannel area from another side (e.g., an inner side) and flow out through the second opening 512. It is noted that while the embodiment of FIG. 5 shows the fluid management core 506 having four microchannel areas 509a-d, any number of microchannel areas may be included in fluid management core 506 depending on the design of the electronic system, such as a chip, SoC, artificial intelligence (AI) device, etc. In some embodiments, fluid connection channels 508 can be also understood as including fluid inlet and outlet to be engaged with the base layer 505, distribution and connection. Overall, it is described herein as the fluid connection channels.

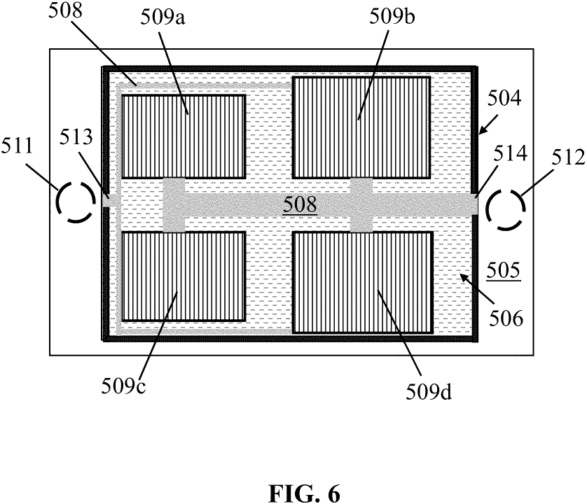

FIG. 6 is a top view of the fluid management core integrated with a base layer according to an embodiment. In FIG. 6, fluid management core 506 has been fully integrated with (e.g., disposed within) the dedicated area 504 of base layer 505 and is engaged with the inlet and outlet fluid channels of base layer 505 (not shown), and with the fluid channels having the first opening 511 and the second opening 512, respectively. As shown, fluid connection channels 508 may include fluid inlet 513 and fluid outlet 514 to be engaged with the base layer 505, distribution and connection.

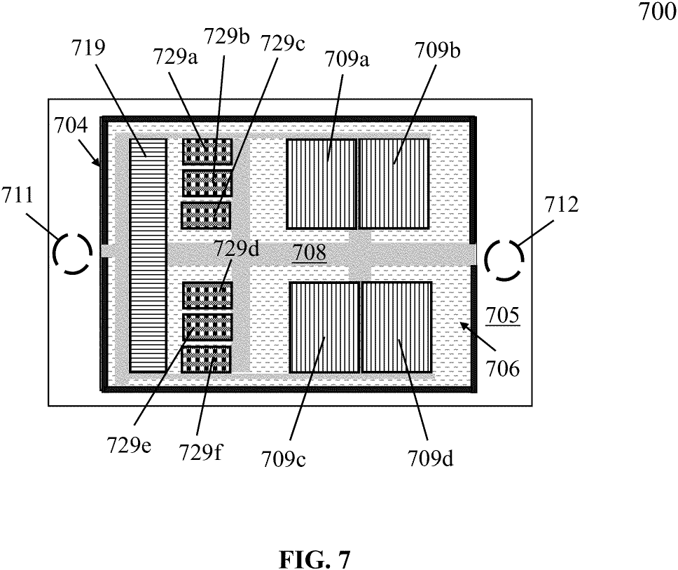

FIG. 7 is a top view of an electronic cooling apparatus having an advanced fluid management core according to an embodiment. As with any of the previously described example electronic cooling apparatuses, electronic cooling apparatus 700 may be customizable to fit on any electronic system, such as a chip, SoC, artificial intelligence (AI) device, etc., to cool the electronic system.

As illustrated in FIG. 7, electronic cooling apparatus 700 may include a base layer 705 having a dedicated area 704 that holds fluid management core 706. Similar to some of the previously described embodiments, the base layer 705 includes a first opening 711 of an inlet fluid channel (not shown) for receiving cooling fluid that flows through the fluid channel and into the fluid management core 706. The base layer 705 further includes a second opening 712 of an outlet fluid channel (also not shown) for warm/hot fluid to escape from the fluid management core 706 and flow out through the fluid channel and the second opening 712.

In FIG. 7, fluid management core 706 may include a multiplicity of microchannel areas or structures of different sizes or dimensions, and configured to cool different electronic components in an electronic system. For example, microchannel areas 709a-d may be designed to cool high power density electronic components, such as ASICs. Microchannel areas 729a-f may be designed to cool low power density components, such as processor cores and/or controller chips. Microchannel area 719 may be designed to cool a memory, such as a dynamic random access memory (DRAM). Therefore, the variation of the internal microchannel areas and fluid connection channels 708 of the fluid management core 706 (i.e., non-uniform cooling distribution) can be customized for different electronic components.

In an embodiment, fluid connection channels 708 (which can be variable or customizable based on the variation of the microchannel areas) are arranged such that incoming cooling fluid entering through the first opening 711 would enter each microchannel area from one side and outgoing warm/hot fluid would escape from each microchannel area from another side and flow out through the second opening 512.

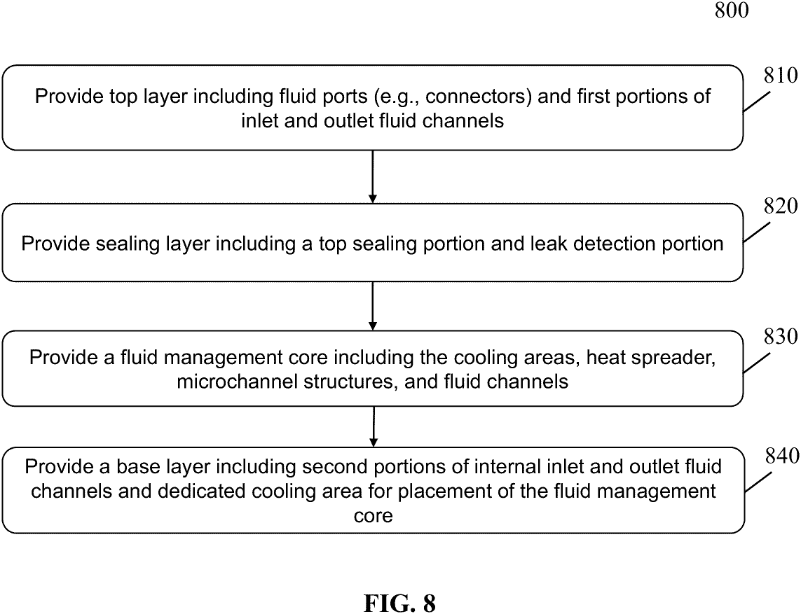

FIG. 8 is a flow diagram illustrating a method of producing an electronic cooling apparatus according to an embodiment. Referring to FIG. 8, at block 810, method 800 includes providing a top layer that includes fluid ports (e.g., connectors) and first portions of internal inlet and outlet fluid channels for supply and return. At block 820, method 800 includes providing a sealing layer that includes a top sealing portion and a leak detection portion. At block 830, method 800 includes providing a fluid management core that includes cooling areas, heat spreader, microchannel areas or structures, and fluid channels. At block 840, method 800 includes providing a base layer including second portions of the internal inlet and outlet fluid channels and a dedicated cooling area for placement of the fluid management core.

In the foregoing specification, embodiments of the invention have been described with reference to specific exemplary embodiments thereof. It will be evident that various modifications may be made thereto without departing from the broader spirit and scope of the invention as set forth in the following claims. The specification and drawings are, accordingly, to be regarded in an illustrative sense rather than a restrictive sense.

What is claimed is:

1. An electronic cooling apparatus, comprising:
a top layer to receive cooling fluid;
a fluid management core including a plurality of microchannel structures to cool electronic components and a plurality of fluid channels through which the cooling fluid is distributed to the microchannel structures;
a base layer including a dedicated cooling area for placement of the fluid management core, and the base layer to provide the cooling fluid to the fluid channels of the fluid management core; and
a sealing layer in between the top layer and the bottom layer to seal the fluid management core.

2. The electronic cooling apparatus of claim 1, wherein the top layer includes a first fluid port and a second fluid port that are respectively connected to an inlet fluid channel and an outlet fluid channel of the electronic cooling apparatus.

3. The electronic cooling apparatus of claim 2, wherein
the top layer further includes a first portion of the inlet fluid channel and a first portion of the outlet fluid channel; and
the base layer further includes a second portion of the inlet fluid channel and a second portion of the outlet fluid channel.

4. The electronic cooling apparatus of claim 2, wherein
the inlet fluid channel directs the cooling fluid received through the first fluid port to the fluid channels of the fluid management core; and
the outlet fluid channel directs warm/hot fluid that escapes from the microchannel structures to the second fluid port.

5. The electronic cooling apparatus of claim 2, wherein
the inlet fluid channel is connected to an inlet through which the cooling fluid is provided to the fluid channels of the fluid management core; and
the outlet fluid channel is connected to an outlet through which warm/hot fluid escapes from the microchannel structures.

6. The electronic cooling apparatus of claim 5, wherein
the base layer further includes a first portion of the inlet and a first portion of the outlet; and
the fluid management core further includes a second portion of the inlet and a second portion of the outlet.

7. The electronic cooling apparatus of claim 1, wherein the sealing layer substantially or entirely covers the fluid management core to form, with the base layer, a contained region that contains the fluid management core.

8. The electronic cooling apparatus of claim 1, wherein the sealing layer includes a leak detection structure to detect any fluid that leaks through the sealing layer.

9. The electronic cooling apparatus of claim 1, wherein the microchannel structures and fluid channels of the fluid management core are variable or customizable to provide non-uniform cooling distribution of different electronic components.

10. An electronic cooling apparatus, comprising:
a top layer to receive cooling fluid;
a plurality of fluid management cores, each fluid management core including a plurality of microchannel structures to cool electronic components and a plurality of fluid channels through which the cooling fluid is distributed to the microchannel structures;
a base layer including a plurality dedicated cooling areas for placement of the fluid management cores, respectively, and the base layer to provide the cooling fluid to the fluid channels of the fluid management cores; and
a sealing layer in between the top layer and the bottom layer to seal the fluid management cores.

11. The electronic cooling apparatus of claim 10, wherein the top layer includes a first fluid port and a second fluid port that are respectively connected to one or more inlet fluid channels and one or more outlet fluid channels of the electronic cooling apparatus.

12. The electronic cooling apparatus of claim 11, wherein
the one or more inlet fluid channels direct the cooling fluid received through the first fluid port to the fluid channels of the fluid management cores; and
the one or more outlet fluid channels direct warm/hot fluid that escapes from the microchannel structures of the fluid management cores to the second fluid port.

13. The electronic cooling apparatus of claim 11, wherein
the one or more inlet fluid channels are connected to one or more inlets through which the cooling fluid is provided to the fluid channels of the fluid management cores; and
the one or more outlet fluid channels are connected to one or more outlets through which warm/hot fluid escapes from the microchannel structures of the fluid management cores.

14. The electronic cooling apparatus of claim 13, wherein
the base layer further includes a first portion of each inlet and a first portion of each outlet; and
one of the fluid management cores includes a second portion of the inlet and a second portion of the outlet.

15. The electronic cooling apparatus of claim 10, wherein the sealing layer substantially or entirely covers the fluid management cores to form, with the base layer, a contained region that contains the fluid management cores.

16. The electronic cooling apparatus of claim 10, wherein the sealing layer includes a leak detection structure to detect any fluid that leaks through the sealing layer.

17. The electronic cooling apparatus of claim 10, wherein the microchannel structures and fluid channels of the fluid management cores are variable or customizable to provide non-uniform cooling distribution of different electronic components.

18. A method, comprising:
providing a top layer including fluid ports, a first portion of an inlet channel, and a first portion of an outlet channel;
providing a sealing layer including a top sealing portion and a leak detection portion;
providing a fluid management core including a plurality of microchannel structures to cool electronic components and a plurality of fluid channels through which cooling fluid is distributed to the microchannel structures; and
providing a base layer including a second portion of the inlet channel, a second portion of the outlet channel, and a dedicated cooling area for placement of the fluid management core.

19. The method of claim 18, wherein the sealing layer is disposed between the top layer and the bottom layer, and form with the base layer, a contained region that contains the fluid management core and to seal the fluid management core.

20. The method of claim 18, wherein the microchannel structures and fluid channels of the fluid management core are variable or customizable to provide non-uniform cooling distribution of different electronic components.
